(19) United States
(12) Patent Application Publication
(10) Pub. No.: US 2009/0273882 A1
(43) Pub. Date: Nov. 5, 2009

(54) CAPACITOR AND METHOD FOR FABRICATING THE SAME

(76) Inventors: Kyung-Woong PARK, Gyeonggi-do (KR); Kee-Jeung LEE, Gyeonggi-do (KR); Deok-Sin KIL, Gyeonggi-do (KR); Young-Dae KIM, Gyeonggi-do (KR); Jin-Hyock KIM, Gyeonggi-do (KR); Kwan-Woo DO, Gyeonggi-do (KR); Jeong-Yeop LEE, Gyeonggi-do (KR)

Correspondence Address: MANNAVA & KANG, P.C., 11240 WAPLES MILL ROAD, Suite 300, FAIRFAX, VA, 22030, US

(21) Appl. No.: 12/427,117

(22) Filed: Apr. 21, 2009

(30) Foreign Application Priority Data
Apr. 30, 2008 (KR) 10-2008-0040923
Dec. 30, 2008 (KR) 10-2008-0137314

(51) Int. Cl. H01G 4/008; H01L 21/02

(52) U.S. Cl. 361/305; 438/386; 438/656; 257/E21.011; 257/E21.008

(57) ABSTRACT

A capacitor includes a first electrode, a dielectric layer, and a second electrode. The capacitor also includes a buffer layer formed over at least one of an interface between the first electrode and the dielectric layer and an interface between the dielectric layer and the second electrode, wherein the buffer layer includes a compound of a metal element from electrode materials of one of the first and second electrodes and a metal element from materials included in the dielectric layer.

### CROSS-REFERENCE TO RELATED APPLICATIONS

The present invention claims priorities of Korean patent application number 10-2008-0040923, filed on Apr. 30, 2008, and Korean patent application number 10-2008-0137314, filed on Dec. 30, 2008, the disclosures of which are incorporated by reference in their entireties.

### BACKGROUND OF THE INVENTION

The present invention relates to a method for fabricating a semiconductor device, and more particularly, to a capacitor and a method for fabricating the same.

As semiconductor devices become highly integrated, the cross-sectional area of a cell is decreasing. Thus, it is difficult to secure a desirable capacitance of a capacitor demanded for device operation. In particular, it has become difficult to form a capacitor which embodies an appropriate capacitance needed to operate a giga-byte class dynamic random access memory (DRAM) device on a semiconductor substrate. Therefore, various methods have been introduced to secure capacitor capacitance.

Development of a high-k multi-component dielectric layer, where k stands for a constant, is being demanded to develop a DRAM device of ultra large-scale integration under 50 nm. Consequently, introduction of noble metal materials having a large work function as an electrode material is also being demanded.

However, using a multi-component dielectric layer may cause a thin film stress due to a lattice mismatch and deteriorate capacitance and leakage current due to a low-k interface layer formation.

### SUMMARY OF THE INVENTION

Embodiments of the present invention are directed to providing a capacitor, which can reduce a thin film stress between a dielectric layer and an electrode, and a method for fabricating the capacitor.

In accordance with an aspect of the present invention, there is provided a capacitor including a first electrode, a dielectric layer, and a second electrode, the capacitor including: a buffer layer formed over at least one of an interface between the first electrode and the dielectric layer and an interface between the dielectric layer and the second electrode, wherein the buffer layer includes a compound of a metal element from electrode materials of one of the first and second electrodes and a metal element from materials included in the dielectric layer.

The first and second electrodes may each include a noble metal or an oxide including a noble metal, and have a single layer structure or a multiple layer structure.

The first and second electrodes having a multiple layer structure may each include a buffer layer formed between a titanium nitride (TiN) layer and a noble metal or an oxide including a noble metal, the buffer layer including a compound of titanium and a noble metal.

The dielectric layer may include a transition metal or an alkaline metal. The transition metal may include titanium (Ti) or tantalum (Ta), and the alkaline metal includes strontium (Sr), barium (Ba), or calcium (Ca).

The dielectric layer may include a dielectric layer selected from a group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

The noble metal may include a metal selected from the group consisting of ruthenium (Ru), iridium (Ir), platinum (Pt), indium (In), and rhodium (Rh). The noble metal may include a metal selected from a group comprising an alloy of Ru and In, an alloy of Ru and Ir, an alloy of In and Ir, an alloy of stannum (Sn) and In, and an alloy of Ru, Ir, and In.

The oxide including a noble metal may include an oxide metal selected from a group comprising RuO₂, SrRuO₃, CaRuO₃, (Ba,Sr)RuO₃, (Ca,Sr)RuO₃, SrIrO₃, CaIrO₃, and (Ba,Sr)IrO₃.

In accordance with another aspect of the present invention, there is provided a method for fabricating a capacitor including a first electrode, a dielectric layer, and a second electrode, the method including: forming a buffer layer over at least one of an interface between the first electrode and the dielectric layer and an interface between the dielectric layer and the second electrode, wherein the buffer layer includes a compound of a metal element from electrode materials of one of the first and second electrodes and a metal element from materials included in the dielectric layer.

The forming of the buffer layer may include performing an atomic layer deposition method. The first electrode and the buffer layer may be formed in substantially the same chamber in-situ.

The performing of the atomic layer deposition method may include using a gas or a reaction gas of a plasma selected from a group comprising ammonia (NH₃), oxygen (O₂), ozone (O₃), nitrous oxide (N₂O), O₂ plasma, and NH₃ plasma.

The method may further include, after the forming of the buffer layer, performing a thermal treatment process. The thermal treatment process may be performed at a temperature ranging from approximately 300° C. to approximately 700° C. in an inert atmosphere.

The method may further include, after the performing of the thermal treatment process, performing an additional thermal treatment process to remove oxygen vacancy. The additional thermal treatment process may be performed at a temperature ranging from approximately 350° C. to approximately 450° C. in an atmosphere of an oxidizing gas.

The first or second electrode and the dielectric layer may be formed in-situ.

### BRIEF DESCRIPTION OF THE DRAWINGS

FIG. 1 illustrates a cross-sectional view of a buffer layer in accordance with embodiments of the present invention.

FIGS. 2A to 2C illustrate cross-sectional views of a capacitor in accordance with embodiments of the present invention.

FIG. 3 is a timing diagram illustrating an atomic layer deposition (ALD) method for forming a buffer layer in accordance with an embodiment of the present invention.

FIG. 4 is a timing diagram describing an ALD method for forming a buffer layer in accordance with an embodiment of the present invention.

FIGS. 5A to 5F are cross-sectional views describing a method for fabricating a capacitor in accordance with an embodiment of the present invention.

### DESCRIPTION OF SPECIFIC EMBODIMENTS

Other objects and advantages of the present invention can be understood by the following description, and become apparent with reference to the embodiments of the present invention.

In the figures, the dimensions of layers and regions may be exaggerated for clear illustration. Also, when a layer (or film) is referred to as being ‘on’ another layer or substrate, it includes a meaning that the layer is directly on the other layer or substrate, or that intervening layers may also be present. Furthermore, when a layer is referred to as being ‘under’ another layer, it includes a meaning that the layer is directly under, or that one or more intervening layers may also be present. In addition, when a layer is referred to as being ‘between’ two layers, it includes a meaning that the layer be the only layer between the two layers, or that one or more intervening layers may also be present.

Embodiments of the present invention relate to a capacitor and a method for fabricating the same. In the embodiments, deterioration of interfacial properties caused by a lattice mismatch may be improved by forming a buffer layer using a compound of one of the metal elements from components of an electrode and a dielectric layer while controlling the dielectric layer and a crystal lattice constant to be alike.

Furthermore, forming a dielectric layer having a preferred orientation may be more conveniently formed according to the embodiments of the present invention, and thus, crystallization temperature may be effectively lowered and a role of oxygen diffusion barrier may be sufficiently fulfilled, preventing oxidation of a bottom plug during a thermal treatment process performed for thin layer formation and crystallization.

Moreover, the adhesive strength between an electrode and a dielectric layer may be improved.

Therefore, a capacitor of a radio frequency (RF) device, which generally requires a high dielectric constant, or a dynamic random access memory (DRAM) capacitor of below 50 nm may be formed by improving crystallinity of a high-k thin layer, wherein k stands for a dielectric constant, and decreasing a crystallization temperature.

The embodiments of the present invention will be described in detail with reference to the accompanying drawings to enable those of ordinary skill in the art to make and use the present invention.

FIG. 1 illustrates a cross-sectional view of a buffer layer in accordance with embodiments of the present invention.

Referring to FIG. 1, a first layer 111 including a metal material is formed. A buffer layer 112 is formed over the first layer 111. A second layer 113 including a metal material is formed over the buffer layer 112.

In particular, the buffer layer 112 is formed to improve interfacial properties between the first layer 111 and the second layer 113. The buffer layer 112 may be formed using a compound including any one of the metal elements included in the first layer 111 and any one of metal elements included in the second layer 113.

The buffer layer 112 may be applied to almost all structures where interfacial property improvement is needed. The buffer layer 112 may be formed between an electrode and a dielectric layer, or between electrodes. For instance, if the first layer 111 includes an electrode, the second layer 113 may include a dielectric layer or a second electrode.

In one embodiment, assuming that the buffer layer 112 is formed between an electrode and a dielectric layer, the first layer 111 may be an electrode including a noble metal and the second layer 113 may be a multi-component dielectric layer. At this time, the buffer layer 112 is formed using a compound including a metal element from components of the noble metal and the multi-component dielectric layer.

When the buffer layer 112 is formed using a compound including a metal element from components of the noble metal and a metal element from components of the multi-component dielectric layer, a thin film stress, which may be caused by a lattice mismatch between the first layer 111 and the second layer 113, i.e., an electrode and a dielectric layer, may be minimized. As a result, formation of a low-k interfacial reaction layer may be reduced and interfacial properties may be improved.

Furthermore, crystallization with preferred orientation may be facilitated at a low temperature, improving the electric characteristic of the second layer 113 which includes a multi-component dielectric layer. Moreover, thermal, chemical, and physical stability may be enhanced at substantially the same time by improving adhesion through securing chemical and structural similarities between the first layer 111 and the second layer 113.

In another embodiment, assuming that the buffer layer 112 is formed between electrodes, the first layer 111 may be a first electrode including a titanium nitride (TiN) layer and the second layer 113 may be a second electrode including strontium ruthenate (SrRuO₃). At this time, the buffer layer 112 is formed using RuTiO which is a compound including titanium (Ti), a metal element from the first layer 111, and ruthenium (Ru), a metal element from the second layer 113.

When the buffer layer 112 is formed using RuTiO, the compound including Ti from the first layer 111 and Ru from the second layer 113, the buffer layer 112 having a lattice constant similar to that of the second layer 113 may facilitate crystallization and function as an oxygen barrier. Thus, a capacitor of a RF device or a DRAM capacitor of below 50 nm may be formed.

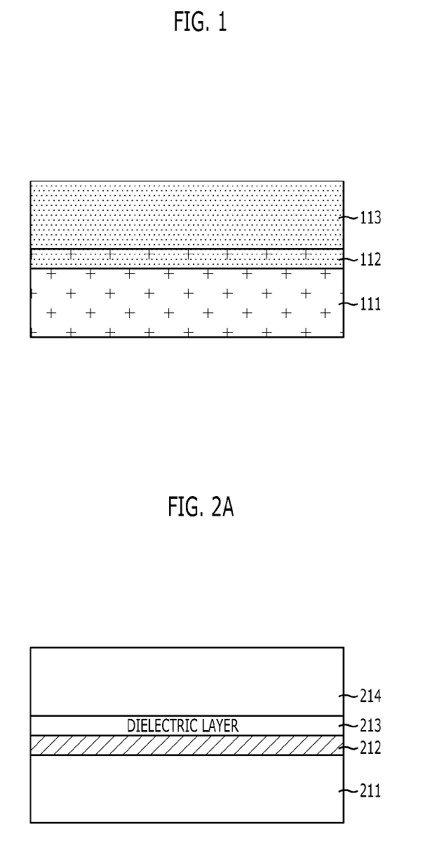

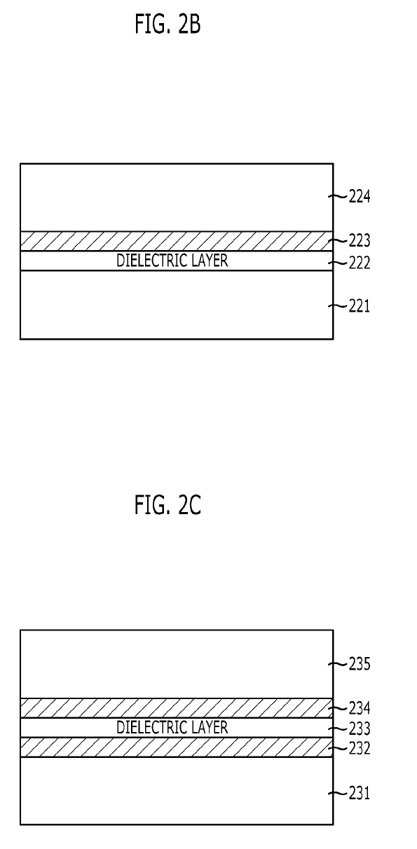

FIGS. 2A to 2C illustrate cross-sectional views of a capacitor in accordance with embodiments of the present invention.

Referring to FIG. 2A, a buffer layer 212 is formed over a bottom electrode 211. A dielectric layer 213 is formed over the buffer layer 212. An upper electrode 214 is formed over the dielectric layer 213.

The bottom electrode 211 and the upper electrode 214 may include a single layer structure or a multiple layer structure. Also, the bottom electrode 211 may be formed using a material including a noble metal. That is, the bottom electrode 211 may be formed using a noble metal or an oxide including a noble metal.

At this time, the noble metal may include a metal selected from the group comprising of ruthenium (Ru), iridium (Ir), platinum (Pt), indium (In), and rhodium (Rh).

Also, the noble metal may include a metal selected from the group comprising an alloy of Ru and In, an alloy of Ru and Ir, an alloy of In and Ir, an alloy of stannum (Sn) and In, and an alloy of Ru, Ir, and In. Furthermore, the oxide including a noble metal may include a metal oxide selected from the group comprising RuO₂, SrRuO₃, CaRuO₃, (Ba,Sr)RuO₃, (Ca,Sr)RuO₃, SrIrO₃, CaIrO₃, and (Ba,Sr)IrO₃. Also, a metal organic source including a cyclopentadienyl (Cp) ligand may be used as a precursor for forming the bottom electrode 211 and the upper electrode 214.

The bottom electrode 211 and the upper electrode 214 having a multiple layer structure may include a stack structure of a titanium nitride (TiN) layer, a noble metal layer or an oxide layer including a noble metal, and a buffer layer formed between the TiN layer and the noble metal layer or the oxide layer including a noble metal. By forming the buffer layer between the TiN layer and the noble metal layer or the oxide layer including a noble metal, the buffer layer having a similar lattice constant may facilitate crystallization and function as an oxygen barrier when forming the noble metal layer or the oxide layer including a noble metal.

The dielectric layer 213 includes a multi-component dielectric layer. The multi-component dielectric layer may include titanium (Ti) or tantalum (Ta). To be specific, the dielectric layer 213 may include a multi-component dielectric layer selected from the group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

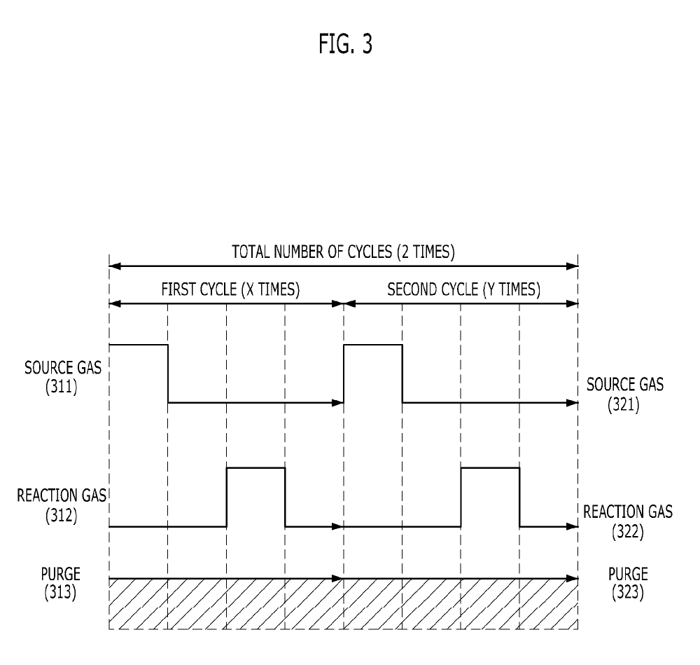

The buffer layer 212 may be formed using a compound including a metal element from materials of the bottom electrode 211 and a metal element from materials of the dielectric layer 213. Also, the buffer layer 212 may be formed using a nano-mix atomic layer deposition method to easily control the composition and lattice constant. The nano-mix atomic layer deposition method will be described in detail in FIG. 3.

In one embodiment, when the bottom electrode 211 includes ruthenium (Ru) and the dielectric layer 213 includes a multi-component high-k dielectric layer such as SrTiO₃ or (BaSr)TiO₃, the buffer layer 212 may be formed between the bottom electrode 211 and the dielectric layer 213 using a metal compound including Ru from the bottom electrode 211 and one or more of Sr and Ti from the dielectric layer 213. In other words, the buffer layer 212 may be formed in a metal compound form such as SrRu and RuTi and in a metal oxide form such as SrRuO and RuTiO.

For instance, the buffer layer 212 having a metal oxide form such as SrRuO or RuTiO may be formed to reduce deterioration of interfacial properties caused by volume expansion when the bottom electrode 211 is oxidized due to oxygen diffusion in an oxidizing atmosphere for forming the high-k dielectric layer.

As described above, forming the buffer layer 212 using a compound of a metal element from the bottom electrode 211 and the dielectric layer 213 may reduce formation of a low-k interfacial reaction layer and improve interfacial properties by minimizing a thin film stress caused by a lattice mismatch between the bottom electrode 211 and the dielectric layer 213. Also, the electric characteristic of the multi-component dielectric layer 213 may be improved by facilitating crystallization with preferred orientation at a low temperature. Moreover, thermal, chemical, and physical stability may be enhanced at substantially the same time by improving adhesion through securing chemical and structural similarities between the bottom electrode 211 and the dielectric layer 213.

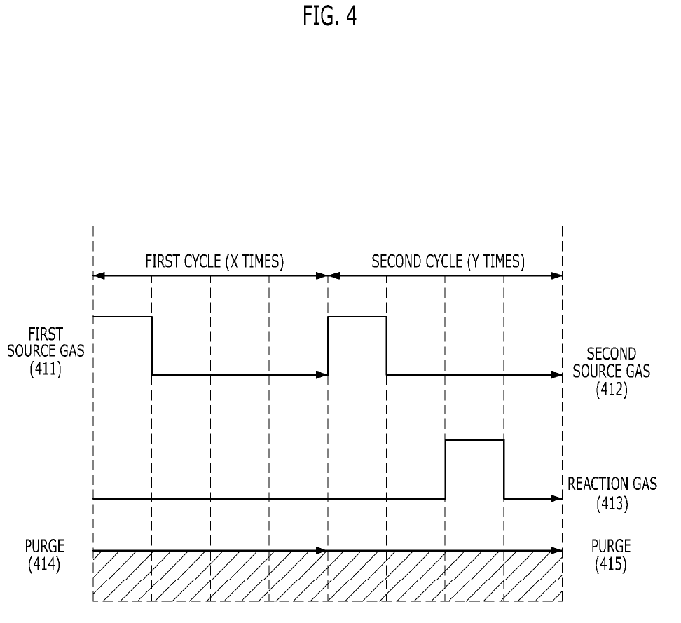

In another embodiment, assuming that the bottom electrode 211 includes a ruthenium (Ru) layer and the dielectric layer 213 includes a strontium (Sr) layer when the bottom electrode 211 includes a noble metal such as Ru and the dielectric layer 213 includes an alkaline metal such as Sr, barium (Ba), or calcium (Ca), the buffer layer 212 may be formed using a metal alloy of SrRu form which is a compound of ruthenium from the bottom electrode 211 and the alkaline metal, i.e., strontium, from the dielectric layer 213. Also, the buffer layer 212 is formed in a manner that the buffer layer 212 is imported on an interface between the bottom electrode 211 and the dielectric layer 213. For instance, the buffer layer 212 is formed by performing a doping in-situ as an extension to the formation of the bottom electrode 211. Forming the buffer layer 212 using the doping method will be described in detail in FIG. 4.

Referring to FIG. 2B, a dielectric layer 222 is formed over a bottom electrode 221. A buffer layer 223 is formed over the dielectric layer 222. An upper electrode 224 is formed over the buffer layer 223. The dielectric layer 222 includes a multi-component dielectric layer. The multi-component dielectric layer may include titanium (Ti) or tantalum (Ta).

To be specific, the dielectric layer 222 may include a multi-component dielectric layer selected from the group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

The bottom electrode 221 and the upper electrode 224 may include a single layer structure or a multiple layer structure. Also, the bottom electrode 221 and the upper electrode 224 may be formed using a material including a noble metal. That is, the bottom electrode 221 and the upper electrode 224 may be formed using a noble metal or an oxide including a noble metal.

At this time, the noble metal may include a metal selected from the group comprising ruthenium (Ru), iridium (Ir), platinum (Pt), indium (In), and rhodium (Rh).

Also, the noble metal may include a metal selected from the group comprising an alloy of Ru and In, an alloy of Ru and Ir, an alloy of In and Ir, an alloy of stannum (Sn) and In, and an alloy of Ru, Ir, and In. Furthermore, the oxide including a noble metal may include a metal selected from the group comprising RuO₂, SrRuO₃, CaRuO₃, (Ba,Sr)RuO₃, (Ca,Sr)RuO₃, SrIrO₃, CaIrO₃, and (Ba,Sr)IrO₃.

The bottom electrode 221 and the upper electrode 224 having a multiple layer structure may include a stack structure of a noble metal layer or an oxide layer including a noble metal, a titanium nitride (TiN) layer, and a buffer layer formed between the noble metal layer or the oxide layer including a noble metal and the TiN layer.

The buffer layer 223 may be formed using a compound including a metal element from materials of the dielectric layer 222 and a metal element from materials of the upper electrode 224. Also, the buffer layer 223 may be formed using a nano-mix atomic layer deposition method to easily control the composition and lattice constant. The nano-mix atomic layer deposition method will be described in detail in FIG. 3.

To be specific, when the dielectric layer 222 includes a multi-component high-k dielectric layer such as SrTiO₃ or (Ba,Sr)TiO₃ and the upper electrode 224 includes ruthenium (Ru), the buffer layer 223 may be formed between the dielectric layer 222 and the upper electrode 224 using a metal compound including Ru from the upper electrode 224 and one or more of Sr and Ti from the dielectric layer 222. In other words, the buffer layer 223 may be formed in a metal compound form such as SrRu and RuTi and in a metal oxide form such as SrRuO and RuTiO. For instance, the buffer layer 223 having a metal oxide form such as SrRuO or RuTiO may be formed to reduce deterioration of interfacial properties caused by volume expansion when the upper electrode 224 is oxidized due to oxygen diffusion in an oxidizing atmosphere for forming the high-k dielectric layer.

As described above, forming the buffer layer 223 using a compound of a metal element from the dielectric layer 222 and the upper electrode 224 may reduce a lattice mismatch and improve adhesion between the dielectric layer 222 and the upper electrode 224.

Referring to FIG. 2C, a capacitor including a stack structure of a bottom electrode 231, a first buffer layer 232, a dielectric layer 233, a second buffer layer 234, and an upper electrode 235 is formed.

The bottom electrode 231 and the upper electrode 235 may include a single layer structure or a multiple layer structure. Also, the bottom electrode 231 and the upper electrode 235 may be formed using a material including a noble metal. That is, the bottom electrode 231 and the upper electrode 235 may be formed using a noble metal or an oxide including a noble metal.

At this time, the noble metal may include a metal selected from the group comprising ruthenium (Ru), iridium (Ir), platinum (Pt), indium (In), and rhodium (Rh).

Also, the noble metal may include a metal selected from the group comprising an alloy of Ru and In, an alloy of Ru and Ir, an alloy of In and Ir, an alloy of stannum (Sn) and In, and an alloy of Ru, Ir, and In. Furthermore, the oxide including a noble metal may include a metal oxide selected from the group comprising RuO₂, SrRuO₃, CaRuO₃, (BaSr)RuO₃, (CaSr)RuO₃, SrIrO₃, CaIrO₃, and (BaSr)IrO₃. Also, a metal organic source including a cyclopentadienyl (Cp) ligand may be used as a precursor for forming the bottom electrode 231.

The bottom electrode 231 and the upper electrode 235 having a multiple layer structure may include a stack structure of a noble metal layer or an oxide layer including a noble metal, a titanium nitride (TiN) layer, and a buffer layer formed between the noble metal layer or the oxide layer including a noble metal and the TiN layer.

The dielectric layer 233 includes a multi-component dielectric layer. The multi-component dielectric layer may include titanium (Ti) or tantalum (Ta). In detail, the dielectric layer 233 may include a multi-component dielectric layer selected from the group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

The first buffer layer 232 may be formed using a compound including a metal element from materials of the bottom electrode 231 and a metal element from materials of the dielectric layer 233. Also, the second buffer layer 234 may be formed using a compound including a metal element from materials of the upper electrode 235 and a metal element from materials of the dielectric layer 233.

If the bottom electrode 231 and the upper electrode 235 are formed using substantially the same material, the first buffer layer 232 and the second buffer layer 234 may also be formed to include substantially the same material. The first buffer layer 232 and the second buffer layer 234 may be formed using a nano-mix atomic layer deposition method to easily control the composition and lattice constant. The nano-mix atomic layer deposition method will be described in detail in FIG. 3.

To be specific, when the bottom electrode 231 includes ruthenium (Ru) and the dielectric layer 233 includes a multi-component high-k dielectric layer such as SrTiO₃ or (BaSr)TiO₃, the first buffer layer 232 may be formed between the bottom electrode 231 and the dielectric layer 233 using a metal compound including Ru from the bottom electrode 231 and one or more of Sr and Ti from the dielectric layer 233. In other words, the first buffer layer 232 may be formed in a metal compound form such as SrRu and RuTi and in a metal oxide form such as SrRuO and RuTiO. For instance, the first buffer layer 232 having a metal oxide form such as SrRuO or RuTiO may be formed to reduce deterioration of interfacial properties caused by volume expansion when the bottom electrode 231 is oxidized due to oxygen diffusion in an oxidizing atmosphere for forming the high-k dielectric layer. The second buffer layer 234 may be formed using a compound including a metal element from components of the upper electrode 235 and the dielectric layer 233, using the above described method.

As described above, forming the first buffer layer 232 using a compound of a metal element from the bottom electrode 231 and the dielectric layer 233 may reduce formation of a low-k interfacial reaction layer and improve interfacial properties by minimizing a thin film stress caused by a lattice mismatch between the bottom electrode 231 and the dielectric layer 233. Also, the electric characteristic of the multi-component dielectric layer 233 may be improved by facilitating crystallization with preferred orientation at a low temperature. Moreover, thermal, chemical, and physical stability may be enhanced at substantially the same time by improving adhesion through securing chemical and structural similarities between the bottom electrode 231 and the dielectric layer 233.

Furthermore, forming the second buffer layer 234 using a compound of a metal element from the dielectric layer 233 and a metal element from the upper electrode 235 may reduce a lattice mismatch and improve adhesion between the dielectric layer 233 and the upper electrode 235.

FIG. 3 illustrates a timing diagram of an atomic layer deposition (ALD) method for forming a buffer layer in accordance with an embodiment of the present invention. In this embodiment of the present invention, a nano-mix ALD method is performed. The nano-mix ALD method includes performing substantially the same process as an atomic layer deposition method.

However, in the nano-mix ALD method, a stack structure where each layer is repeatedly formed to a very small thickness is formed. In particular, each layer in the stack structure is formed to a thickness below the deposition thickness limit where the layers can be mixed, and as a result, the stack structure becomes a compound form. In this embodiment of the present invention, an ALD method for forming a RuTiO layer is described.

An ALD method generally includes forming a thin layer using the following process as one cycle. A source gas is supplied to chemically adsorb a source layer on a substrate surface and a purge gas is supplied to purge residues of physically adsorbed sources. A reaction gas is supplied to the source layer to chemically react the source layer and the reaction gas, thereby forming a desired atomic thin layer. A purge gas is supplied to purge residues of the reaction gas. Otherwise, a purge gas may be continuously supplied while supplying a source gas and a reaction gas as it is shown in this embodiment of the present invention.

The above described ALD method uses a surface reaction mechanism which allows obtaining a stable and uniform thin layer. Thus, the ALD method may be used in a structure having a large height difference or having a small design rule.

Also, the above described ALD method generally reduces particles generated by gas phase reaction compared to a chemical vapor deposition (CVD) method because a source gas and a reaction gas are supplied and purged separately in a sequential order.

Referring to FIG. 3, an ALD method includes a first cycle for forming a ruthenium oxide layer and a second cycle for forming a titanium oxide layer. Although the first and second cycles include a three step process of source gas/reaction gas/purge, the purge gas may be continuously supplied while performing the ALD method.

The first cycle for forming the ruthenium oxide layer includes a first process 311 of supplying a ruthenium source gas, a second process 312 of supplying a reaction gas, and a third process 313 of supplying a purge gas. The first cycle is performed at a temperature ranging from approximately 250° C. to approximately 450° C.

At this time, after the first process 311 is performed, a period of time passes before the second process 312 is performed. After the second process 312 is performed, another period of time passes before the first process 311 is performed again. In other words, the ALD method includes performing the first process 311 of supplying a ruthenium source gas, the third process 313 of supplying a purge gas, the second process 312 of supplying a reaction gas, and the third process 313 of supplying a purge gas in a sequential order in substance because the third process 313 is continuously performed between the first process 311 and the second process 312.

The first process 311 includes supplying a source gas. The first process 311 may include flowing a ruthenium precursor into a deposition chamber.

The second process 312 includes supplying a reaction gas. The second process 312 may use a reaction gas selected from the group comprising oxygen (O₂), ozone (O₃), nitrous oxide (N₂O), and O₂ plasma in the deposition chamber.

The third process 313 includes supplying a purge gas. The third process 313 may remove non-reacted gas from the deposition chamber by flowing nitrogen gas in the deposition chamber.

As described above, the first cycle for forming a ruthenium oxide layer is repeatedly performed for X number of times to form a ruthenium oxide layer having a desirable thickness, and at this time, the number X is controlled in a manner that the ruthenium oxide layer is formed to have a thickness below the deposition thickness limit for mixing the ruthenium oxide layer.

The second cycle for forming a titanium oxide layer includes a first process 321 of supplying a titanium source gas, a second process 322 of supplying a reaction gas, and a third process 323 of supplying a purge gas. The second cycle is performed at a temperature ranging from approximately 250° C. to approximately 450° C. At this time, after the first process 321 is performed, a period of time passes before the second process 322 is performed. After the second process 322 is performed, another period of time passes before the first process 321 is performed again. In other words, the ALD method includes performing the first process 321 of supplying a titanium source gas, the third process 323 of supplying a purge gas, the second process 322 of supplying a reaction gas, and the third process 323 of supplying a purge gas in a sequential order in substance because the third process 323 is continuously performed between the first process 321 and the second process 322.

The first process 321 includes supplying a source gas. The first process 321 may include flowing a titanium precursor into a deposition chamber.

The second process 322 includes supplying a reaction gas. The second process 322 may use a reaction gas selected from the group comprising O₂, O₃, N₂O, ammonia (NH₃), O₂ plasma, and NH₃ plasma in the deposition chamber.

The third process 323 includes supplying a purge gas. The third process 323 may remove non-reacted gas from the deposition chamber by flowing nitrogen gas in the deposition chamber.

As described above, the second cycle for forming a titanium oxide layer is repeatedly performed for Y number of times to form a titanium oxide layer having a desirable thickness, and at this time, the number Y is controlled in a manner that the titanium oxide layer is formed to have a thickness below the deposition thickness limit for mixing the titanium oxide layer.

At this time, the number of times the first and second cycles is repeated may differ according to the kind of materials, apparatuses, and conditions, and each layer being formed in each cycle is formed to a thickness below the deposition thickness limit for mixing.

A RuTiO layer having a mixed form is ultimately formed by repeating the first cycle for X number of times, repeating the second cycle for Y number of times, and repeating the first and second cycles for Z number of times to stack a desired number of layers. The numbers X, Y, and Z represent natural numbers.

In particular, the number of repeated deposition times for the first and second cycles may be controlled in a manner that a lattice constant of a compound including two elements ranges from approximately 3.4 Å to approximately 3.9 Å.

Furthermore, the number of deposition times may be controlled in a manner that a composition ratio, or a volume ratio, of titanium, which is a transition metal element, ranges from approximately 10% to approximately 70% within RuTiO.

Although the ALD method for forming RuTiO is described in this embodiment of the present invention, the embodiment was described for convenience of description. The ALD method may be applied to nearly all processes for forming a buffer layer as shown in FIGS. 1 to 2C.

FIG. 4 is a timing diagram describing an ALD method for forming a buffer layer in accordance with an embodiment of the present invention. The ALD method is performed to form a metal alloy in a compound form on an interface between a bottom electrode and a dielectric layer.

The ALD method includes performing a doping in-situ as an extension to a bottom electrode formation. In this embodiment, an ALD method for forming an alloy of strontium (Sr) and ruthenium (Ru) is described.

Referring to FIG. 4, the ALD method includes a first cycle for forming a ruthenium layer and a second cycle for forming a strontium layer. The first cycle includes a two step process of first source and gas/purge, and the second cycle includes a three step process of second source, gas/reaction and gas/purge. However, a purge gas may be continuously flowed while performing the ALD method.

The first cycle for forming a ruthenium layer includes a first process 411 of supplying a ruthenium source gas and a second process 414 of supplying a purge gas. The first cycle is performed at a temperature ranging from approximately 250° C. to approximately 450°0 C. While the first process 411 is performed for one period of time, the second process 414 is continuously performed throughout the first cycle.

The first process 411 includes supplying a first source gas. The first process 411 may include flowing a ruthenium precursor into a deposition chamber.

The second process 414 includes supplying a purge gas. The second process 414 may include removing non-reacted gas from the deposition chamber by flowing nitrogen gas into the deposition chamber.

As described above, the first cycle for forming a ruthenium layer is repeatedly performed for X number of times to form a ruthenium layer having a desirable thickness, thereby forming a bottom electrode.

A strontium layer is formed by doping in-situ to form a metal alloy on an interface between the bottom electrode and a dielectric layer.

The second cycle for forming a strontium layer includes a first process 412 of supplying a strontium source gas, a second process 413 of supplying a reaction gas, and a third process 415 of supplying a purge gas. The second cycle is performed at a temperature ranging from approximately 250° C. to approximately 450° C.

At this time, after the first process 412 is performed, a period of time passes before the second process 413 is performed. After the second process 413 is performed, another period of time passes before the first process 412 is performed again. In other words, the ALD method includes performing the first process 412 of supplying a strontium source gas, the third process 415 of supplying a purge gas, the second process 413 of supplying a reaction gas, and the third process 415 of supplying a purge gas in a sequential order in substance because the third process 415 is continuously performed between the first process 412 and the second process 413.

The first process 412 includes supplying a second source gas. The first process 412 may include flowing a strontium precursor into a deposition chamber.

The second process 413 includes supplying a reaction gas. The second process 413 may use a reaction gas selected from the group comprising oxygen (O₂), ozone (O₃), nitrous oxide (N₂O), ammonia (NH₃), O₂ plasma, and NH₃ plasma in the deposition chamber.

The third process 415 includes supplying a purge gas. The third process 415 may remove non-reacted gas from the deposition chamber by flowing nitrogen gas in the deposition chamber.

As described above, the second cycle for forming a strontium layer is repeatedly performed for Y number of times to form a strontium layer having a desirable thickness, and at this time, the number Y is controlled in a manner that the strontium layer is formed to have a thickness below the deposition thickness limit for mixing the strontium layer.

That is, formation of the strontium layer is controlled in a manner to have a thickness which allows metal alloying in a compound form because the strontium layer is formed over the ruthenium layer through doping to form an alloy of Sr and Ru.

The number of times the first and second cycles is repeated may differ according to the kind of materials, apparatuses, and conditions.

A buffer layer may be formed over an interface between a bottom electrode and a dielectric layer shown in FIG. 2A using the above described deposition process. At this time, a process margin may be secured by forming the bottom electrode and the buffer layer in substantially the same chamber in-situ.

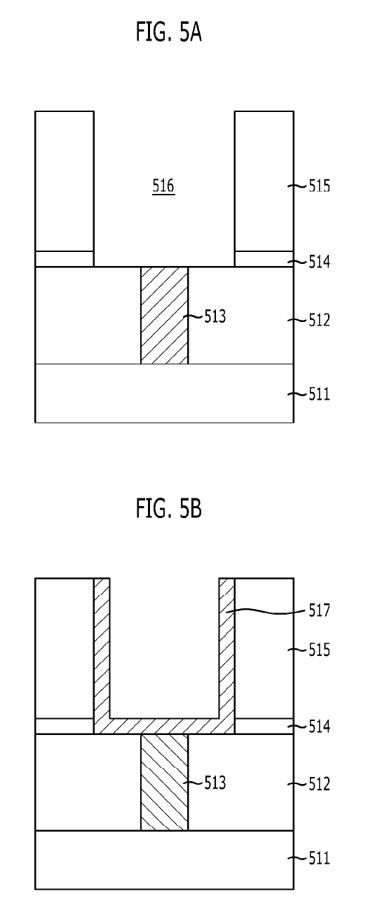

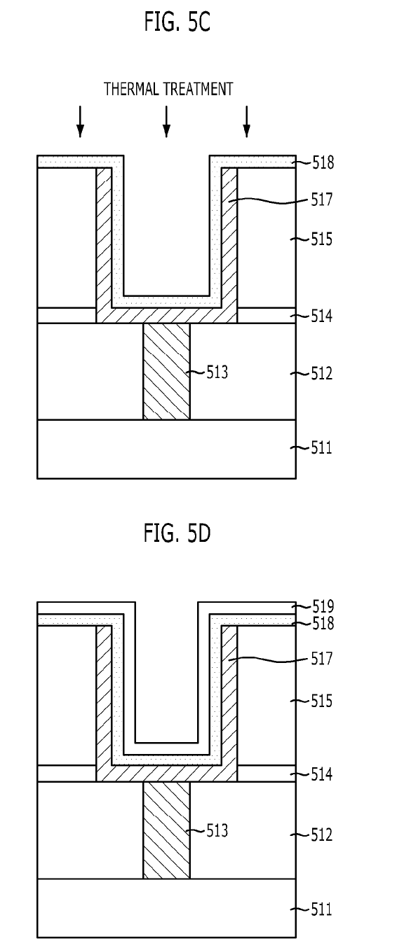

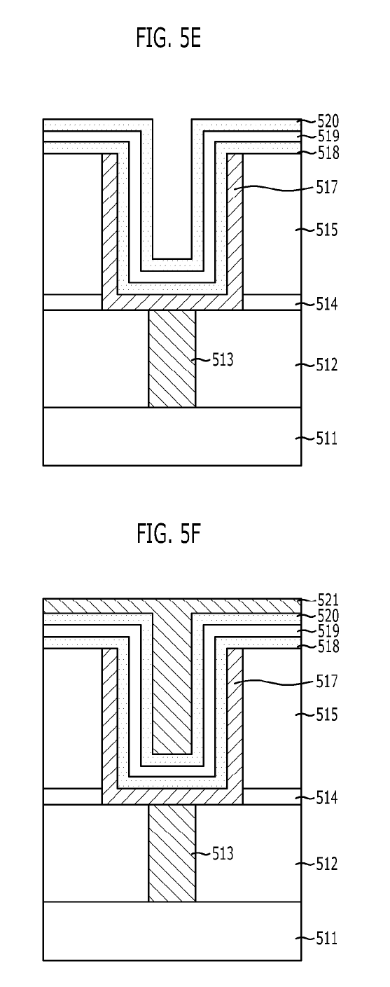

FIGS. 5A to 5F are cross-sectional views describing a method for fabricating a capacitor in accordance with an embodiment of the present invention. The capacitor in this present invention may be formed in a shape selected from the group comprising a flat plate, a concave, a cylinder, and a pillar. In this embodiment of the present invention, a concave type capacitor is described as an example.

Referring to FIG. 5A, an inter-layer dielectric layer 512 is formed over a substrate 511. The substrate 511 may include a semiconductor substrate on which a dynamic random access memory (DRAM) process is being performed or a semi-finished substrate including gate patterns and bit line patterns. The inter-layer dielectric layer 512 is formed to provide inter-layer insulation for the substrate 511 and an upper capacitor. The inter-layer dielectric layer 512 may include an oxide-based layer. The oxide-based layer may include an oxide-based layer selected from the group comprising a high density plasma (HDP) oxide layer, a borophosphosilicate glass (BPSG) layer, a phosphosilicate glass (PSG) layer, a boron silicate glass (BSG) layer, a tetraethyl orthosilicate (TEOS) layer, an undoped silicate glass (USG) layer, a fluorinated silicate glass (FSG) layer, a carbon doped oxide (CDO) layer, an organo silicate glass (OSG) layer, and a combination thereof. Also, the oxide-based layer may include a layer formed using a spin coating method such as a spin on dielectric (SOD) layer.

A storage node contact plug 513 is formed, penetrating the inter-layer dielectric layer 512 and coupled to the substrate 511. The storage node contact plug 513 is formed by etching an insulation layer for forming the inter-layer dielectric layer 512 to form a contact hole exposing a portion of the substrate 511, burying a conductive material over the contact hole, and performing a planarization process on the substrate structure until a surface of the inter-layer dielectric layer 512 is exposed.

The conductive material may include a conductive material selected from the group comprising a transition metal layer, a rare earth metal layer, an alloy layer of the transition metal layer and the rare earth metal layer, and a silicide layer of the transition metal layer and the rare earth metal layer. Also, the conductive material may include a polycrystalline silicon layer doped with impurity ions.

Furthermore, the above described conductive materials may include a stack structure of two or more layers. When the storage node contact plug 513 includes a metal layer, e.g., transition metal or rare earth metal, a barrier metal layer (not shown) may be further formed between the storage node contact plug 513 and the contact hole. In this embodiment of the present invention, the conductive material includes polysilicon.

An etch stop layer is formed over the inter-layer dielectric layer 512. The etch stop layer is formed to stop etching when forming a contact hole for forming a subsequent bottom electrode, thereby preventing the inter-layer dielectric layer 512 from getting damaged. The etch stop layer is also formed to prevent a solution from penetrating into the inter-layer dielectric layer 512 during a dip out process for forming a cylinder type capacitor.

Thus, the etch stop layer is formed using a material having an etch selectivity with respect to the inter-layer dielectric layer 512 and a subsequent sacrificial layer. The etch stop layer may include a nitride-based layer, and the nitride-based layer may include a silicon nitride layer, e.g., SiN or Si₃N₄.

A sacrificial layer is formed over the etch stop layer. The sacrificial layer is formed to provide a contact hole for forming a bottom electrode. The sacrificial layer may include an oxide-based layer having a single layer structure or a multiple layer structure. The oxide-based layer may include an oxide-based layer selected from the group comprising a high density plasma (HDP) oxide layer, a borophosphosilicate glass (BPSG) layer, a phosphosilicate glass (PSG) layer, a boron silicate glass (BSG) layer, a tetraethyl orthosilicate (TEOS) layer, an undoped silicate glass (USG) layer, a fluorinated silicate glass (FSG) layer, a carbon doped oxide (CDO) layer, an organo silicate glass (OSG) layer, and a combination thereof. Also, the oxide-based layer may include a layer formed using a spin coating method such as a spin on dielectric (SOD) layer.

The sacrificial layer and the etch stop layer are etched to form a storage node hole 516 exposing the storage node contact plug 513, thereby forming a sacrificial pattern 515 and an etch stop pattern 514. The storage node hole 516 defines a region where a bottom electrode is to be formed. The storage node hole 516 may be formed by forming a mask pattern over the sacrificial layer and etching the sacrificial layer and the etch stop layer using the mask pattern as an etch barrier.

The mask pattern may be formed by forming a photoresist layer over the sacrificial layer and performing a photo-exposure and developing process to pattern the photoresist layer in a manner that the region predetermined for a storage node hole is exposed. A hard mask layer may be additionally formed before forming the photoresist layer to secure an etch margin which is not fully provided by the photoresist layer.

Referring to FIG. 5B, a bottom electrode 517 is formed over the substrate structure. The bottom electrode 517 may include a single layer structure or a multiple layer structure. Also, the bottom electrode 517 may include a material including a noble metal. That is, the bottom electrode 517 may include a noble metal or an oxide including a noble metal.

At this time, the noble metal may include a metal selected from the group comprising ruthenium (Ru), iridium (Ir), platinum (Pt), indium (In), and rhodium (Rh). Also, the noble metal may include a metal selected from the group comprising an alloy of Ru and In, an alloy of Ru and Ir, an alloy of In and Ir, an alloy of stannum (Sn) and In, and an alloy of Ru, Ir, and In.

Furthermore, the oxide including a noble metal may include a metal oxide selected from the group comprising RuO₂, SrRuO₃, CaRuO₃, (Ba,Sr)RuO₃, (Ca,Sr)RuO₃, SrIrO₃, CaIrO₃, and (Ba,Sr)IrO₃. Also, a metal organic source including a cyclopentadienyl (Cp) ligand may be used as a precursor for forming the bottom electrode 517.

The bottom electrode 517 having a multiple layer structure may include a stack structure of a titanium nitride (TiN) layer, a noble metal layer or an oxide layer including a noble metal, and a buffer layer formed between the TiN layer and the noble metal layer or the oxide layer including a noble metal. The buffer layer may be formed using an atomic layer deposition (ALD) method shown in FIG. 3 or FIG. 4. By forming the buffer layer between the TiN layer and the noble metal layer or the oxide layer including a noble metal in the bottom electrode 517 having a multiple layer structure, the buffer layer having a similar lattice constant facilitates crystallization and fulfills a role as an oxygen barrier when forming the noble metal layer or the oxide layer including a noble metal.

Referring to FIG. 5C, a first buffer layer 518 is formed over the substrate structure. The first buffer layer 518 may include a compound of a metal element from materials of the bottom electrode 517 and a metal element from a subsequent dielectric layer. Also, the first buffer layer 518 may be formed using a nano-mix atomic layer deposition method, shown in FIGS. 3 and 4, to easily control the composition and lattice constant.

To be specific, when the bottom electrode 517 includes ruthenium (Ru) and a subsequent dielectric layer includes a multi-component high-k dielectric layer such as SrTiO₃ or (BaSr)TiO₃, the first buffer layer 518 may be formed between the bottom electrode 517 and the dielectric layer using a metal compound including Ru from the bottom electrode 517 and one or more of Sr and Ti from the dielectric layer. In other words, the first buffer layer 518 may be formed in a metal compound form such as SrRu and RuTi and in a metal oxide form such as SrRuO and RuTiO. For instance, the first buffer layer 518 having a metal oxide form such as SrRuO or RuTiO may be formed to reduce deterioration of interfacial properties caused by volume expansion when the bottom electrode 517 is oxidized due to oxygen diffusion in an oxidizing atmosphere for forming the high-k dielectric layer.

A thermal treatment process is performed on the first buffer layer 518. The thermal treatment process is performed so that the first buffer layer 518 may easily function as a crystallization seed layer for the subsequent dielectric layer.

The thermal treatment process may be performed at a temperature ranging from approximately 300° C. to approximately 700° C. Also, the thermal treatment process is performed in an inert atmosphere. For instance, an inert gas including nitrogen (N₂) or argon (Ar) may be used.

After the thermal treatment process is performed, an additional thermal treatment process may be performed to remove oxygen vacancy. The additional thermal treatment process may be performed at a temperature ranging from approximately 350° C. to approximately 450° C. in the atmosphere of an oxidizing gas selected from the group comprising oxygen (O₂), ozone (O₃), and nitrous oxide (N₂O).

Referring to FIG. 5D, a dielectric layer 519 is formed over the first buffer layer 518. The dielectric layer 519 includes a multi-component dielectric layer. The multi-component dielectric layer may include titanium (Ti) or tantalum (Ta).

In detail, the dielectric layer 519 may include a multi-component dielectric layer selected from the group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

As described above, forming the first buffer layer 518 using a compound of a metal element from the bottom electrode 517 and a metal element from the dielectric layer 519 while performing a nano-mix ALD method to control the dielectric layer 519 and a crystalline lattice constant to become almost alike may reduce formation of a low-k interfacial reaction layer and improve interfacial properties by minimizing a thin film stress caused by a lattice mismatch between the bottom electrode 517 and the dielectric layer 519. Also, the electric characteristic of the multi-component dielectric layer 519 may be improved by facilitating crystallization with preferred orientation at a low temperature, efficiently lowering a crystallization temperature.

Moreover, the first buffer layer 518 functions as an oxygen diffusion barrier. As a result, a bottom plug may be prevented from oxidation during a thermal treatment process for forming a thin film and crystallization. Also, the first buffer layer 518 improves thermal, chemical, and physical stability at substantially the same time by improving adhesion through securing chemical and structural similarities between the bottom electrode 517 and the dielectric layer 519.

Referring to FIG. 5E, a second buffer layer 520 is formed over the dielectric layer 519. The second buffer layer 520 may include a compound of a metal element from the dielectric layer 519 and a metal element from a subsequent upper electrode. Also, the second buffer layer 520 may be formed using a nano-mix atomic layer deposition method shown in FIG. 3 to more easily control the composition and lattice constant.

To be specific, when the dielectric layer 519 includes a multi-component high-k dielectric layer such as SrTiO₃ or (Ba,Sr)TiO₃ and a subsequent upper electrode includes ruthenium (Ru), the second buffer layer 520 may be formed between the dielectric layer 519 and the upper electrode using a metal compound including Ru from the upper electrode and one or more of Sr and Ti from the dielectric layer 519. In other words, the second buffer layer 520 may be formed in a metal compound form such as SrRu and RuTi and in a metal oxide form such as SrRuO and RuTiO. For instance, the second buffer layer 520 having a metal oxide form such as SrRuO or RuTiO may be formed to reduce deterioration of interfacial properties caused by volume expansion when the upper electrode is oxidized due to oxygen diffusion in an oxidizing atmosphere for forming the high-k dielectric layer.

A thermal treatment process is performed on the second buffer layer 520. The thermal treatment process may be performed at a temperature ranging from approximately 300° C. to approximately 700° C. Also, the thermal treatment process is performed in an inert atmosphere. For instance, an inert gas including N₂ or Ar may be used.

After the thermal treatment process is performed, an additional thermal treatment process may be performed to remove oxygen vacancy. The additional thermal treatment process may be performed at a temperature ranging from approximately 350° C. to approximately 450° C. in the atmosphere of an oxidizing gas selected from the group comprising O₂, O₃, and N₂O.

As described above, forming the second buffer layer 520 using a compound including a metal element from the dielectric layer 519 and the upper electrode allows reducing a lattice mismatch between the dielectric layer 519 and the upper electrode as well as improving adhesion.

Referring to FIG. 5F, an upper electrode 521 is formed over the second buffer layer 520. The upper electrode 521 may include a single layer structure or a multiple layer structure. Also, the upper electrode 521 may include a material including a noble metal. That is, the upper electrode 521 may include a noble metal or an oxide including a noble metal. At this time, the noble metal may include a metal selected from the group comprising ruthenium (Ru), iridium (Ir), platinum (Pt), indium (In), and rhodium (Rh). Also, the noble metal may include a metal selected from the group comprising an alloy of Ru and In, an alloy of Ru and Ir, an alloy of In and Ir, an alloy of stannum (Sn) and In, and an alloy of Ru, Ir, and In. Furthermore, the oxide including a noble metal may include a metal oxide selected from the group comprising RuO₂, SrRuO₃, CaRuO₃, (Ba,Sr)RuO₃, (Ca,Sr)RuO₃, SrIrO₃, CaIrO₃, and (Ba,Sr)IrO₃.

The upper electrode 521 having a multiple layer structure may include a stack structure of a noble metal layer or an oxide layer including a noble metal, a titanium nitride layer, and a buffer layer formed between the noble metal layer or the oxide layer including a noble metal and the titanium nitride layer.

While the present invention has been described with respect to the specific embodiments, it will be apparent to those skilled in the art that various changes and modifications may be made without departing from the spirit and scope of the invention as defined in the following claims.

What is claimed is:

1. A capacitor including a first electrode, a dielectric layer, and a second electrode, the capacitor comprising:
a buffer layer formed over at least one of an interface between the first electrode and the dielectric layer and an interface between the dielectric layer and the second electrode,
wherein the buffer layer includes a compound of a metal element from electrode materials of one of the first and second electrodes and a metal element from materials included in the dielectric layer.

2. The capacitor of claim 1, wherein the first and second electrodes each comprise a noble metal or an oxide including a noble metal.

3. The capacitor of claim 1, wherein the first and second electrodes each have a single layer structure or a multiple layer structure.

4. The capacitor of claim 3, wherein the first and second electrodes having a multiple layer structure each comprise a buffer layer formed between a titanium nitride (TiN) layer and a noble metal or an oxide including a noble metal, the buffer layer including a compound of titanium and a noble metal.

5. The capacitor of claim 1, wherein the dielectric layer includes a transition metal or an alkaline metal.

6. The capacitor of claim 5, wherein the transition metal includes titanium (Ti) or tantalum (Ta), and the alkaline metal includes strontium (Sr), barium (Ba), or calcium (Ca).

7. The capacitor of claim 5, wherein the dielectric layer includes a dielectric layer selected from a group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

8. The capacitor of claim 2, wherein the noble metal includes a metal selected from a group comprising ruthenium (Ru), iridium (Ir), platinum (Pt), indium (In), and rhodium (Rh).

9. The capacitor of claim 2, wherein the noble metal includes a metal selected from a group comprising an alloy of Ru and In, an alloy of Ru and Ir, an alloy of In and Ir, an alloy of stannum (Sn) and In, and an alloy of Ru, Ir, and In.

10. The capacitor of claim 2, wherein the oxide including a noble metal includes a metal selected from a group comprising RuO₂, SrRuO₃, CaRuO₃, (Ba,Sr)RuO₃, (Ca,Sr)RuO₃, SrIrO₃, CaIrO₃, and (Ba,Sr)IrO₃.

11. A method for fabricating a capacitor including a first electrode, a dielectric layer, and a second electrode, the method comprising:
forming a buffer layer over at least one of an interface between the first electrode and the dielectric layer and an interface between the dielectric layer and the second electrode,
wherein the buffer layer includes a compound of a metal element from electrode materials of one of the first and second electrodes and a metal element from materials included in the dielectric layer.

12. The method of claim 11, wherein the first and second electrodes each include a noble metal or an oxide including a noble metal.

13. The method of claim 11, wherein the first and second electrodes each have a single layer structure or a multiple layer structure.

14. The method of claim 13, wherein the first and second electrodes having a multiple layer structure each comprise a buffer layer formed between a titanium nitride (TiN) layer and a noble metal or an oxide including a noble metal, the buffer layer including a compound of titanium and a noble metal.

15. The method of claim 11, wherein the dielectric layer includes one of a transition metal and an alkaline metal.

16. The method of claim 15, wherein the transition metal includes titanium (Ti) or tantalum (Ta), and the alkaline metal includes strontium (Sr), barium (Ba), or calcium (Ca).

17. The method of claim 16, wherein the dielectric layer includes a dielectric layer selected from a group comprising TiO₂, Ta₂O₅, SrTiO₃, CaTiO₃, (Sr,Ca)TiO₃, (Ba,Sr)TiO₃, SrTaO₃, CaTaO₃, and (Ba,Sr)TaO₃.

18. The method of claim 12, wherein the noble metal includes a metal selected from a group comprising ruthenium (Ru), iridium (Ir), platinum (Pt), indium (In), and rhodium (Rh).

19. The method of claim 12, wherein the noble metal includes a metal selected from a group comprising an alloy of Ru and In, an alloy of Ru and Ir, an alloy of In and Ir, an alloy of stannum (Sn) and In, and an alloy of Ru, Ir, and In.

20. The method of claim 12, wherein the oxide including a noble metal includes a metal selected from a group comprising RuO₂, SrRuO₃, CaRuO₃, (Ba,Sr)RuO₃, (Ca,Sr)RuO₃, SrIrO₃, CaIrO₃, and (Ba,Sr)IrO₃.

21. The method of claim 11, wherein the forming of the buffer layer includes performing an atomic layer deposition method.

22. The method of claim 11, wherein the first electrode and the buffer layer are formed in substantially the same chamber in-situ.

23. The method of claim 21, wherein the performing of the atomic layer deposition method includes using a gas or a reaction gas of a plasma selected from a group comprising ammonia (NH₃), oxygen (O₂), ozone (O₃), nitrous oxide (N₂O), O₂ plasma, and NH₃ plasma.

24. The method of claim 11, further comprising, after the forming of the buffer layer, performing a thermal treatment process.

25. The method of claim 24, wherein the thermal treatment process is performed at a temperature ranging from approximately 300° C. to approximately 700° C.

26. The method of claim 24, wherein the thermal treatment process is performed in an inert atmosphere.

27. The method of claim 24, further comprising, after the performing of the thermal treatment process, performing an additional thermal treatment process to remove oxygen vacancy.

28. The method of claim 27, wherein the additional thermal treatment process is performed at a temperature ranging from approximately 350°0 C. to approximately 450° C.

29. The method of claim 27, wherein the additional thermal treatment process is performed in an atmosphere of an oxidizing gas.

30. The method of claim 11, wherein the first or second electrode and the dielectric layer are formed in-situ.
